(19) United States
(12) Patent Application Publication
(10) Pub. No.: US 2021/0111539 A1
(43) Pub. Date: Apr. 15, 2021

(54) DILUTE NITRIDE BASED LASERS, PHOTODETECTORS, AND SENSING SYSTEMS

(71) Applicant: Array Photonics, Inc., Tempe, AZ (US)

(72) Inventors: Sabeur SIALA, Sunnyvale, CA (US); Radek ROUCKA, East Palo Alto, CA (US); Aymeric MAROS, San Francisco, CA (US)

(21) Appl. No.: 17/070,666

(22) Filed: Oct. 14, 2020

Related U.S. Application Data
(60) Provisional application No. 62/914,632, filed on Oct. 14, 2019.
(60) Provisional application No. 62/916,397, filed on Oct. 17, 2019.

(51) Int. Cl. H01S 5/183; H01S 5/02; H01S 5/30; H01S 5/20; H01L 31/0304; H01L 31/16

(52) U.S. Cl. CPC H01S 5/18375; H01S 5/0206; H01S 5/3013; H01S 5/34353; H01L 31/0304; H01L 31/16; H01S 5/2027

(57) ABSTRACT

Disclosed herein is a laser structure comprising an active region overlying a GaAs substrate. The active region includes a dilute nitride material. The laser is configured to generate light at wavelengths greater than 1300 nm. Also disclosed herein is a photodetector comprising an absorber layer overlying a GaAs substrate. The absorber layer includes a dilute nitride material. The photodetector is configured to detect light at wavelengths greater than 1300 nm. Exemplary dilute nitride materials may include, but are not limited to, GaInNAs and GaInNAsSb. Embodiments of the disclosure may include a dilute nitride-on-GaAs laser structure and a dilute nitride-on-GaAs photodetector.

### CROSS-REFERENCE TO RELATED APPLICATIONS

This application claims the benefit under 35 U.S.C. § 119(e) of U.S. Provisional Application No. 62/914,632, filed Oct. 14, 2019 and U.S. Provisional Application No. 62/916,397, filed Oct. 17, 2019, the contents of which are incorporated herein by reference in their entirety for all purposes.

### FIELD OF THE DISCLOSURE

This disclosure relates generally to short wavelength infrared (SWIR) optoelectronic devices, including photodetectors and lasers, and more specifically, dilute nitride based optoelectronic devices operating in a wavelength range including 1300 nm to 1500 nm.

### BACKGROUND OF THE DISCLOSURE

Optoelectronic devices operating in the wavelength range between 400 nm to 1800 nm have a wide range of applications, including fiber optic communications, sensing, and imaging. Traditionally, compound III-V semiconductor materials are used to make such devices. Indium gallium arsenide (InGaAs) materials are usually grown on indium phosphide (InP) substrates. The composition and thickness of the InGaAs layers are chosen to provide the required functionality, such as light emission or absorption at desired wavelengths of light and are also lattice matched or very closely lattice matched to the InP substrate, in order to produce high quality materials that have low levels of crystalline defects, and high levels of performance.

Although optoelectronic devices including InGaAs on InP materials currently dominate the short wavelength infrared (SWIR) market, the material system has several limitations, such as being expensive due to the high cost of InP substrates, having low yields due to the fragility of InP substrates, and having size limits due to the limited diameter of InP substrates (and associated quality issues at larger diameters). It has been specifically challenging to make InP-based vertical-cavity surface emitting lasers (VCSELs) for high volume applications. Additionally, the lack of availability of 6″ InP epi wafers limits the adoption of InGaAs detectors in consumer markets.

From a manufacturing perspective, and also an economic perspective, gallium arsenide (GaAs) represents a better substrate choice. However, the large lattice mismatch between GaAs and InGaAs alloys required for SWIR devices produces poor quality materials that compromise electrical and optical performance. Attempts have been made to produce long wavelength (greater than 1.2 μm) materials for optoelectronic devices on GaAs based on dilute nitride materials such as GaInNAs and GaInNAsSb. However, where device performance is reported, it has been much poorer than for InGaAs/InP devices. For example, the dilute nitride-based devices that have been reported to date have very low responsivity, which makes the devices unsuited for practical sensing and detection applications.

Thus, to take advantage of the manufacturing scalability and cost advantages of GaAs substrates, there is continued interest in developing long wavelength materials on GaAs substrates that have improved optoelectronic performance. What is needed is GaAs-based optoelectronic devices that enable high-volume production of infrared lasers and detectors operating in a wavelength range including 1300 nm to 1500 nm. These GaAs-based optoelectronic devices may be able to overcome major cost and scalability challenges faced by competing InP-based technologies.

### BRIEF SUMMARY OF THE DISCLOSURE

Disclosed herein is a laser structure comprising an active region overlying a GaAs substrate. The active region includes a dilute nitride material. The laser is configured to generate light at wavelengths greater than 1300 nm. Also disclosed herein is a photodetector comprising an absorber layer overlying a GaAs substrate. The absorber layer includes a dilute nitride material. The photodetector is configured to detect light at wavelengths greater than 1300 nm. Exemplary dilute nitride materials may include, but are not limited to, GaInNAs and GaInNAsSb. Embodiments of the disclosure may include a dilute nitride-on-GaAs laser structure and a dilute nitride-on-GaAs photodetector.

### BRIEF DESCRIPTION OF THE DRAWINGS

The drawings described herein are for illustration purposes only. The drawings are not intended to limit the scope of the present disclosure.

FIG. 1A illustrates an exemplary plot of quantum efficiency as a function of wavelength for dilute nitride materials, according to embodiments of the disclosure.

FIG. 1B illustrates an exemplary diagram showing the wavelength operation of dilute nitride materials on GaAs substrates, according to embodiments of the disclosure.

FIG. 2A illustrates a scanning electron microscope image of an exemplary Fabry Perot edge-emitting laser including two dilute nitride QWs, according to embodiments of the disclosure.

FIG. 2B illustrates an output power vs. current density plot of an exemplary Fabry Perot edge-emitting laser including two dilute nitride QWs, according to embodiments of the disclosure.

FIG. 3A illustrates SEM images of an exemplary broad-area ridge waveguide edge emitting laser on GaAs substrate, according to embodiments of the disclosure.

FIG. 3B illustrates output power vs. current density plots of an exemplary broad-area ridge waveguide edge emitting laser on GaAs substrate, according to embodiments of the disclosure.

FIG. 4A illustrates an exemplary ridge waveguide edge emitting laser on GaAs, according to embodiments of the disclosure.

FIG. 4B illustrates exemplary gratings for a laser fabricated using nano-imprint lithography, according to embodiments of the disclosure.

FIG. 5 illustrates a cross-sectional view of an exemplary multi-wavelength ridge-waveguide laser array, according to embodiments of the disclosure.

FIG. 6 illustrates a cross-sectional view of an exemplary monolithically stacked EEL, according to embodiments of the disclosure.

FIG. 7A illustrates maximum permission exposures for a laser operating with different pulse widths, according to embodiments of the disclosure.

FIG. 7B illustrates the maximal allowed continuous wave power for different lasers, according to embodiments of the disclosure.

FIG. 8 illustrates a cross-sectional view of an exemplary stack for a VCSEL, according to some embodiments.

FIG. 9A illustrates a cross-sectional view of an exemplary intracavity VCSEL, according to embodiments of the disclosure.

FIG. 9B illustrates an output power vs. current density plot of an exemplary intracavity p-contact VCSEL on GaAs substrate, according to embodiments of the disclosure.

FIG. 9C illustrates the peak emission wavelength of an exemplary intracavity p-contact VCSEL on GaAs substrate, according to embodiments of the disclosure.

FIG. 10 illustrates a cross-sectional view of an exemplary VCSEL including a tunnel junction, according to embodiments of the disclosure.

FIG. 11 illustrates a cross-sectional view of an exemplary bottom-emitting VCSEL, according to embodiments of the disclosure.

FIG. 12 illustrates a planar view of an exemplary bottom-emitting VCSEL, according to embodiments of the disclosure.

FIG. 13 illustrates a cross-sectional view of an exemplary bottom-emitting VCSEL implemented using flip-chip packaging, according to embodiments of the disclosure.

FIG. 14 illustrates a scanning electron microscope image of etched microlenses formed in a GaAs substrate, according to embodiments of the disclosure.

FIG. 15 illustrates a scanning electron microscope image of collimating lenses formed in a GaAs substrate, according to embodiments of the disclosure.

FIGS. 16A-16B illustrate top views and responsivity curves from an exemplary dilute nitride-on-GaAs based photodetector, according to embodiments of the disclosure.

FIG. 17A illustrates an exemplary structure for a dilute nitride-on-GaAs avalanche photodiode, according to embodiments of the disclosure.

FIG. 17B illustrates test results from an exemplary p-i-n diode structure with compositional and thickness variations in the dilute nitride layer, according to embodiments of the disclosure.

FIG. 18 illustrates an exemplary sun spectral irradiance, according to embodiments of the disclosure.

### DETAILED DESCRIPTION OF THE INVENTION

Disclosed herein is a laser structure comprising an active region overlying a GaAs substrate. The active region includes a dilute nitride material. The laser is configured to generate light at wavelengths greater than 1300 nm. Also disclosed herein is a photodetector comprising an absorber layer overlying a GaAs substrate. The absorber layer includes a dilute nitride material. The photodetector is configured to detect light at wavelengths greater than 1300 nm. Exemplary dilute nitride materials may include, but are not limited to, GaInNAs and GaInNAsSb. Embodiments of the disclosure may include a dilute nitride-on-GaAs laser structure and a dilute nitride-on-GaAs photodetector.

The following description is presented to enable a person of ordinary skill in the art to make and use various embodiments. Descriptions of specific devices, techniques, and applications are provided only as examples. These examples are being provided solely to add context and aid in the understanding of the described examples. It will thus be apparent to a person of ordinary skill in the art that the described examples may be practiced without some or all of the specific details. Other applications are possible, such that the following examples should not be taken as limiting. Various modifications in the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

Various techniques and process flow steps will be described in detail with reference to examples as illustrated in the accompanying drawings. In the following description, numerous specific details are set forth in order to provide a thorough understanding of one or more aspects and/or features described or referenced herein. It will be apparent, however, to a person of ordinary skill in the art, that one or more aspects and/or features described or referenced herein may be practiced without some or all of these specific details. In other instances, well-known process steps and/or structures have not been described in detail in order to not obscure some of the aspects and/or features described or referenced herein.

In the following description of examples, reference is made to the accompanying drawings which form a part hereof, and in which it is shown by way of illustration specific examples that can be practiced. It is to be understood that other examples can be used and structural changes can be made without departing from the scope of the disclosed examples.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combination of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

The term “lattice matched,” as used herein means that the referenced materials have the same lattice constant or a lattice constant differing by less than +/−0.2%. For example, GaAs and AlAs are lattice matched, having lattice constants differing by 0.12%.

The term “layer,” as used herein, means a continuous region of a material (e.g., an alloy) that can be uniformly or non-uniformly doped and that can have a uniform or a non-uniform composition across the region.

The term “bandgap,” as used herein, is the energy difference between the condition and valence bands of a material.

The term “responsivity,” as used herein is the ratio of the generated photocurrent to the incident light power at a given wavelength.

Exemplary Tunability of Dilute Nitride Materials

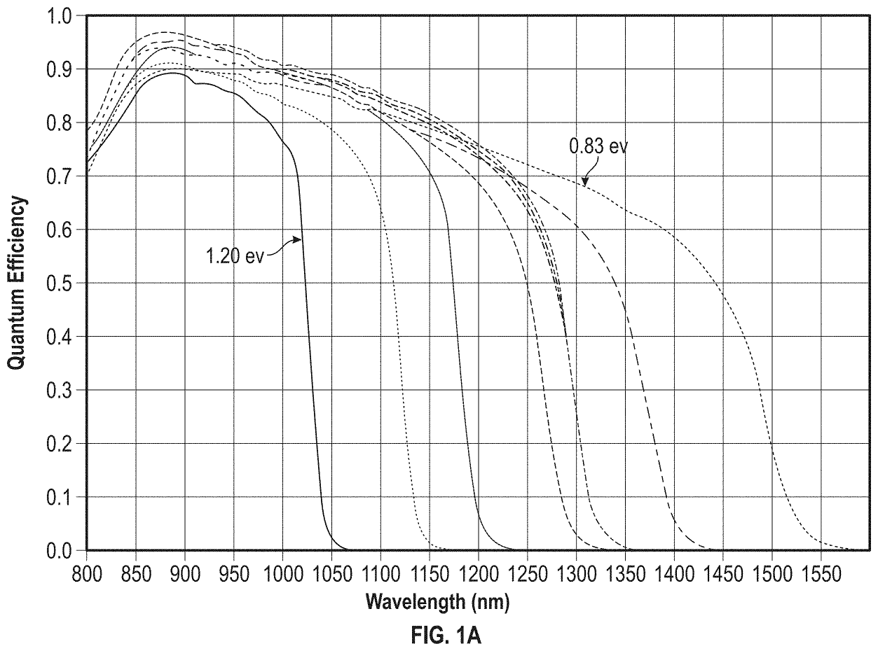

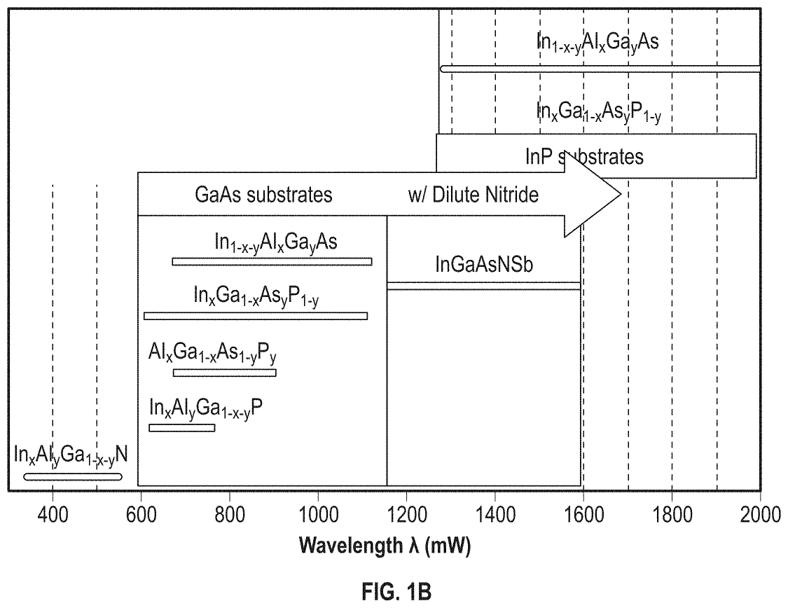

Dilute nitride materials provide high quality, lattice matched and bandgap tunable materials. FIG. 1A illustrates an exemplary plot of quantum efficiency as a function of wavelength for dilute nitride materials, according to embodiments of the disclosure. As shown in the figure, the bandgap of the dilute nitride materials may be tuned for operating in different wavelength ranges. The bandgap may be tuned by incorporating dilute amounts of nitrogen and varying indium, antimony, or both. While the bandgap is being tuned, the material may be configured to remain lattice matched to GaAs. This bandgap tunability, along with the availability of 6″ GaAs substrate and mature fabrication processes, can enable high-volume production of broadband and extended wavelength photodetectors for 3D spectroscopy, for example.

FIG. 1B illustrates an exemplary diagram showing the wavelength operation of dilute nitride materials on GaAs substrates, according to embodiments of the disclosure. As discussed above, GaAs substrates offer several advantages over InP substrates when used for optoelectronic devices. Dilute nitride materials (e.g., InGaAsNSb) on GaAs substrates may be used to achieve longer wavelength operation (up to 1600 nm). Thus, dilute nitride semiconductors extend the low cost, mature, high-volume GaAs capability into the InP territory, as shown in the figure. The mature GaAs-based epi technology can be leveraged for, e.g., vertical cavity surface emitting laser (VCSEL) arrays.

Thus, dilute nitride-on-GaAs technology may provide an attractive balance of performance and cost relative to InGaAs/InP technology. Dilute nitride-on-GaAs may provide significantly lower costs and the ability to scale to high volumes for consumer applications, something that is challenging for InGaAs/InP.

Exemplary Dilute Nitride-on-GaAs Lasers

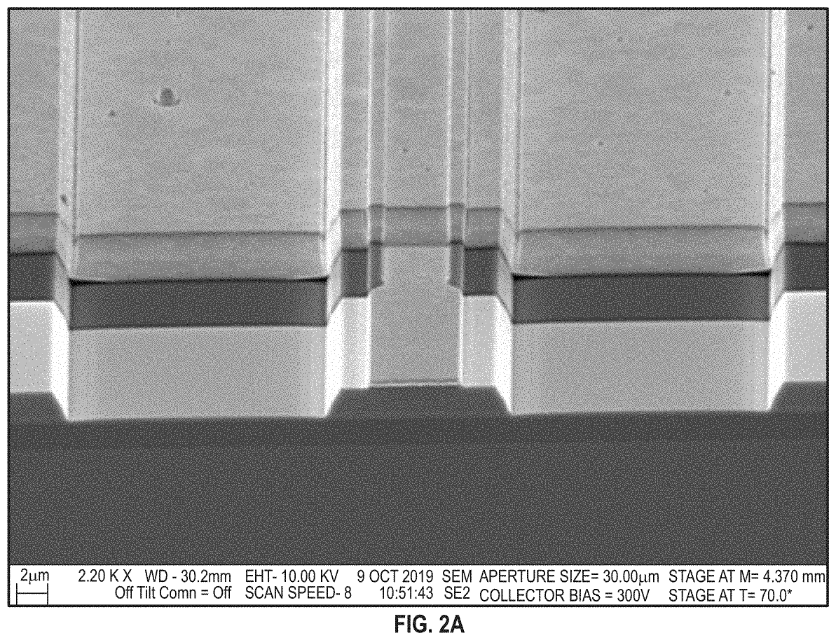

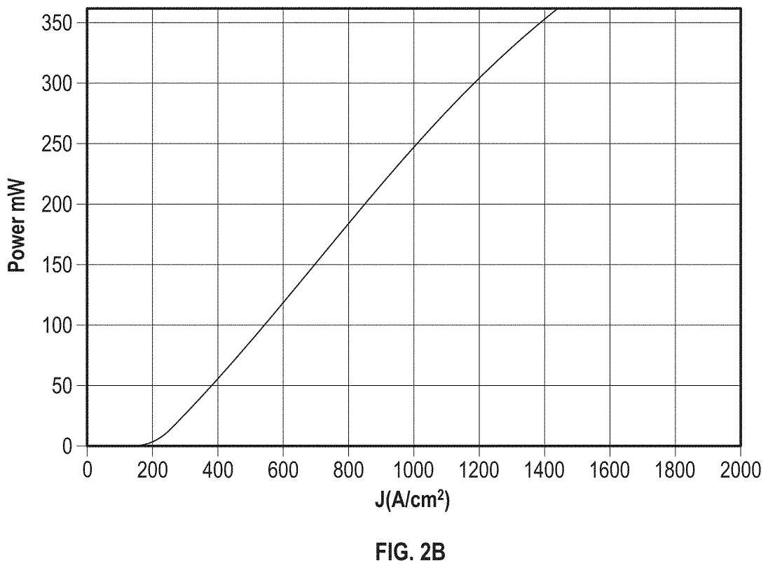

Dilute nitride quantum wells (QWs) may achieve good performance, having low full-width maximum (FWHM) and low threshold current densities (e.g., 100-120 A/cm² per QW). FIGS. 2A-2B illustrate a scanning electron microscope (SEM) image and an output power vs. current density plot, respectively, of an exemplary Fabry Perot (FP) edge-emitting laser (EEL) including two dilute nitride QWs, according to embodiments of the disclosure.

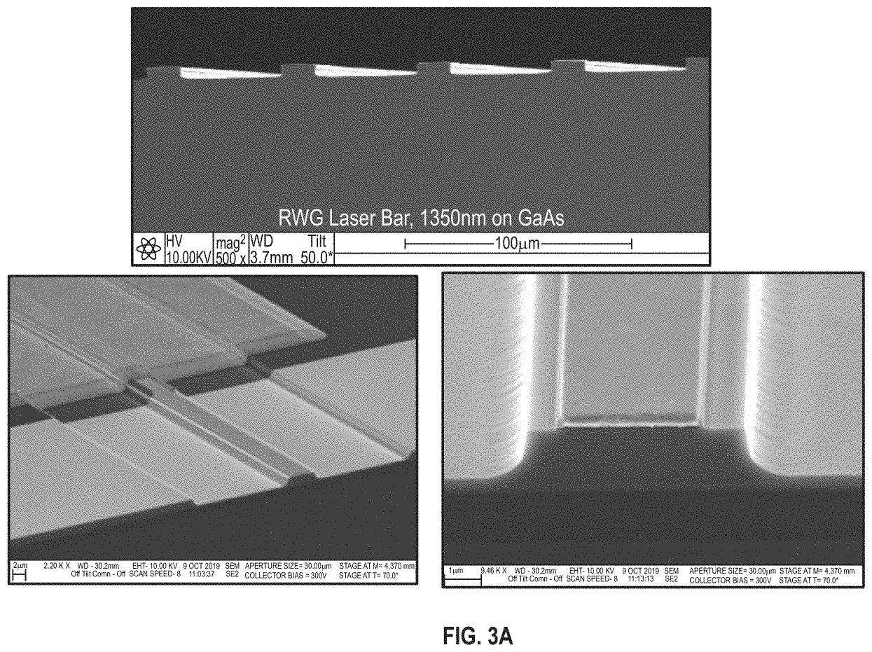

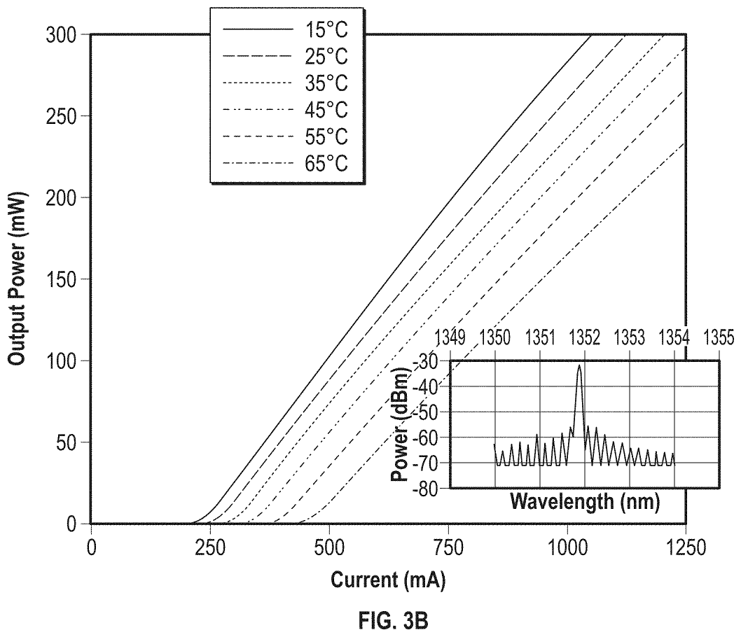

FIGS. 3A-3B illustrate SEM images and output power vs. current density plots, respectively, of an exemplary broad-area ridge waveguide EEL on GaAs substrate, according to embodiments of the disclosure. The broad-area ridge waveguide EEL may include two QWs, a ridge waveguide width of about 50 μm, a cavity length of about 1800 μm, and uncoated facets. The ridge waveguide may be formed using both wet and dry etching. As shown in FIG. 3B, the broad-area ridge waveguide EEL may have a peak wavelength around 1350 nm. When operated with 2A current in pulsed mode (e.g., 1 μs pulse and 1% duty cycle), over 0.5 W is obtained. As shown, high performance dilute nitride EELs may be achieved by incorporating packaging and fabrication techniques used for high-power and high-brightness 800 nm-900 nm GaAs laser bar stacks. Unlike GaAs-based bar stacks, gold-tin solders have been problematic for InP-based bar stack assemblies. Additionally, the fabrication of high brightness, narrow linewidth distributed Bragg reflector (DBR) and distributed feedback (DFB) lasers for coherent applications is simpler. For example, DBR lasers may be formed using a single growth epi that does not require an epitaxial overgrowth. The dilute nitride lasers may have many applications including medical, cosmetic, and automotive light detection and ranging (LIDAR).

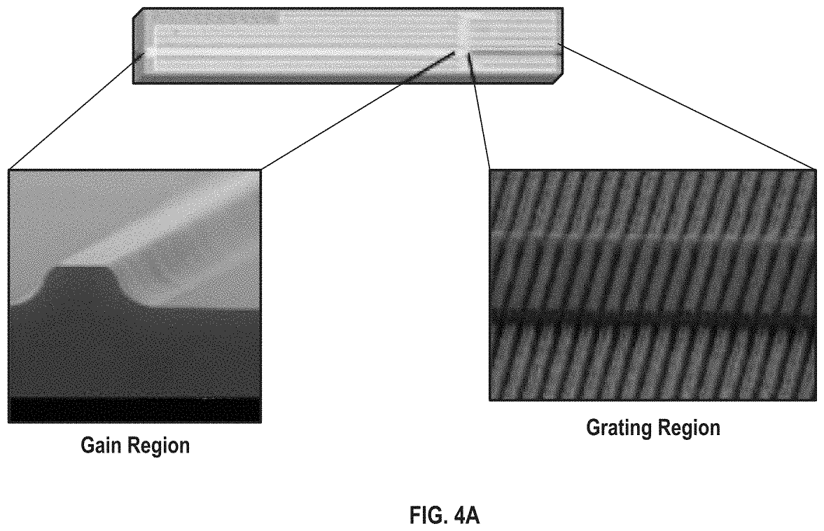

One application for narrow linewidth 1350 nm and 1500 nm DBR or DFB laser arrays on GaAs substrate may include frequency modulated continuous wave (FMCW) chip-scale LIDAR sensors. These lasers may be fabricated using an exemplary ridge waveguide EEL, as shown in FIG. 4A. In some embodiments, the gratings for the laser may be fabricated using nano-imprint lithography (NIL), as shown in FIG. 4B. NIL is much easier on GaAs materials compared to InP materials due to the mechanical fragility of InP substrates. Additionally, the laser had better temperature stability when formed on a GaAs substrate compared to when formed on an InP substrate. The narrow linewidth lasers may be used for applications that determine the range and velocity of moving targets, multi-beam Doppler LIDARs for automotive, industrial, shipping and logistics, and the like.

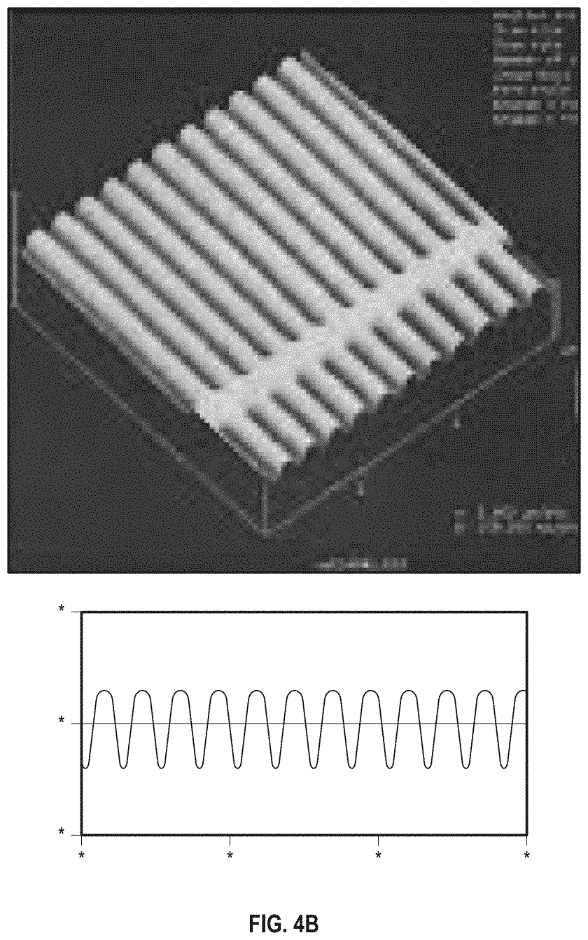

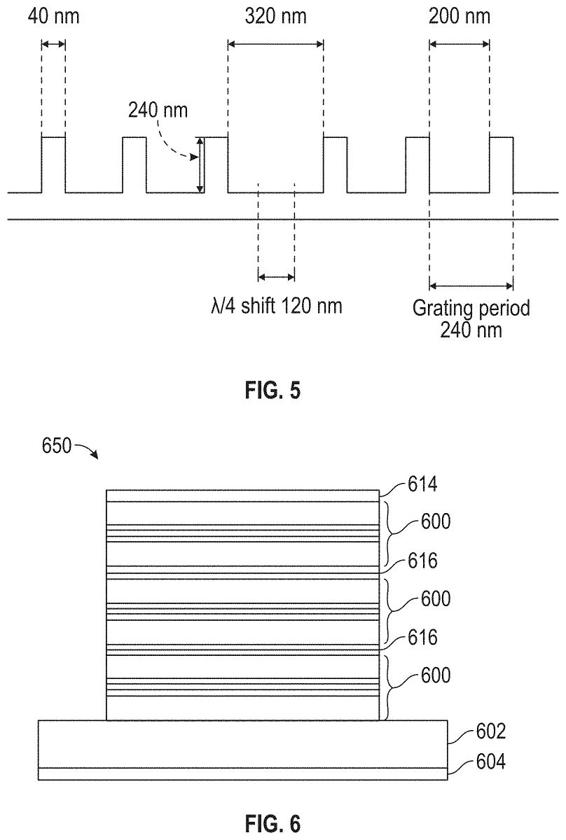

Another exemplary type of dilute nitride laser may include a multi-wavelength ridge-waveguide laser array that emits light in the wavelength range of 1400 nm-2400 nm. FIG. 5 illustrates a cross-sectional view of an exemplary multi-wavelength ridge-waveguide laser array, according to embodiments of the disclosure. The laser array may include a plurality of laser bars emitting a plurality (e.g., 100-120) of wavelengths. In some embodiments, each laser bar may be a multi-wavelength array with nano-imprinted DBR or DFB gratings. In some embodiments, the laser array may include different materials systems. For example, the laser array may include an InGaAsP/InP EEL array emitting light at 1400 nm-1950 nm, and a GaSb-based laser array emitting light at 1950 nm-2400 nm. The InGaAsP/InP EEL array and the GaSb-based laser array may be DFB or DBRs formed using NIL patterning.

Although the figure shows a multi-wavelength ridge-wavelength laser having a 40 nm ridge width, a 240 nm ridge height, 200 nm and 320 nm grating spacings between sidewalls of adjacent laser bars, and a grating period of 240 nm, embodiments of the disclosure may include other ridge widths, ridge heights, grating spacings, and grating periods.

In some embodiments, a dilute nitride-on-GaAs laser may be a monolithically stacked EEL. FIG. 6 illustrates a cross-sectional view of an exemplary monolithically stacked EEL, according to embodiments of the disclosure. The monolithically stacked EEL 650 may include a substrate 602, a bottom contact layer 604, a plurality of monolithically grown laser diodes 600, and a top contact layer 614. The laser diodes 600 may be connected via tunnel junctions 616 for high current density. The substrate 602 may be overlaying the bottom contact layer 604, the laser diodes 600 may be overlaying the substrate 602, and the top contact layer 614 may be overlaying the laser diodes.

The tunnel junctions 616 may lead to high output power density without mechanical laser diode stacking. The monolithically stacked EEL 650 may operate in the 1200-1500 nm range, which may have better higher eye-safety limits than a 905 nm laser, for example. In some embodiments, the monolithically stacked EEL 650 may emit light in the 1300 nm range. The monolithically stacked EEL 650 may be formed such that certain target specifications are achieved. Exemplary target specifications may include, but are not limited to, an emitting area of 200 μm×10 μm, a beam profile of 10° and 25° (FF, FWHM), high power, and a duty cycle range of up to 0.2%, short pulse widths (e.g., less than 4 ns), and an array of four or more channels. The monolithically stacked EEL may be used for applications such as pulsed laser sources for LIDARs and medical applications.

Although the figure illustrates three laser structures 600 and two tunnel junctions 616, embodiments of the disclosure may include any number of laser structures and any number of (e.g., at least one) tunnel junctions. For example, a laser may include two laser structures and one tunnel junction, four laser structures and three tunnel junctions, etc.

Embodiments of the disclosure can include dilute nitride optoelectronic devices used for emitting in the wavelength range of 1300-1500 nm. 1300-1500 nm photonics may be in the eye-safety wavelength range. The cornea of the human eyes may absorb light having wavelengths greater than 1350 nm, and the retina may absorb light having wavelengths less than 1100 nm. Thus, the retina may not be damaged by 1300-1500 nm lasers.

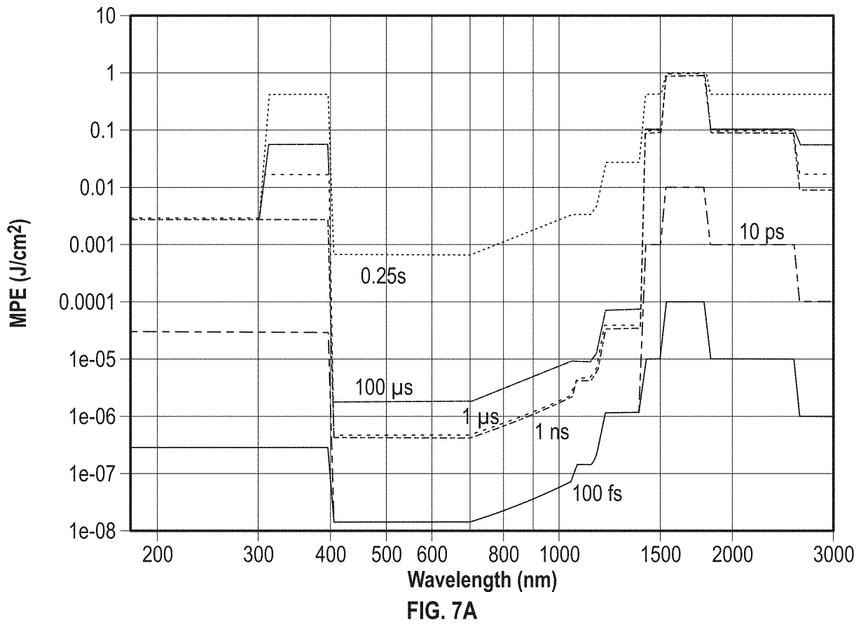

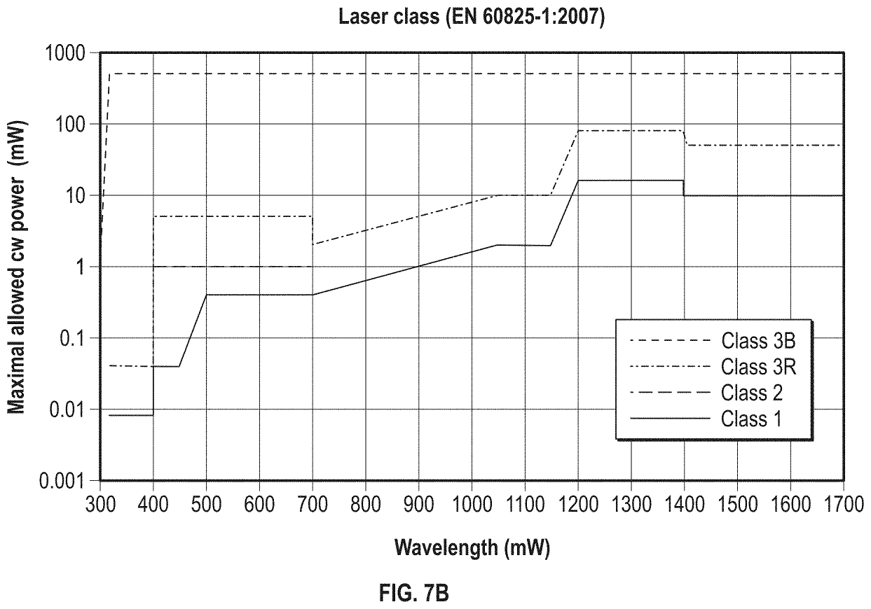

For a laser operating with a 1 ns pulse, the laser safety limit at 1300 nm is about 100,000 times higher than at 905 nm, as shown in FIG. 7A. For a laser operating in continuous wave mode, the laser safety limit at 1300 nm is about 15 times higher and at 1500 nm is about 10 times higher than at 905 nm, as shown in FIG. 7B.

Embodiments of the disclosure may include dilute nitride QWs used in other types of lasers, such as VCSELs. VCSELs are a class of semiconductor lasers with many applications and may offer various advantages when compared to EELs. The planar structure of VCSELs, configured to provide light emission along an axis that is transverse to the layers of the semiconductor structure, allows on-wafer testing (before dicing and packaging of individual devices or arrays); the ability to form both one-dimensional and two-dimensional arrays; low divergence output beams that facilitate efficient coupling to optical fibers, waveguides, and other optical elements; the use of traditional low-cost light emitting diode (LED) packaging technology; as well as integration with electronic, optoelectronic, and optical elements, high reliability, and high efficiency.

VCSELs have many applications. One application is 3D sensing in, e.g., smartphones and mobile devices. For example, VCSELs can be used for world-facing time-of-flight (ToF) cameras for smartphones. VCSELs may be used for face, object, scene, and/or gesture recognition. VCSELs may also be used for laser light transmission through organic light emitting diode (OLED) screens. Additionally, VCSELs arrays operating in the 1300 nm range may have improved performance, being eye-safe and operating in a longer wavelength range for superior outdoor performance, compared to 940 nm VCSELs.

Another application is automotive in-cabin sensing. VCSELs arrays may be used for driver monitoring, gesture control, and face recognition. The 1300 nm-1500 nm VCSELs being eye-safe may be useful for longer distances to extend the capabilities in larger vehicles. Additionally, 1300 nm-1500 nm VCSELs may have better performance in ambient sunlight.

Another application is short-range LIDARs for internet of things (IoT), robotics, and security. Robotics applications can include robots for home use. Security applications may include transactions based on facial recognition (e.g., identity checks at airports, self-checkouts at stores, etc.).

VCSELs may also be used for LIDARs for autonomous vehicles, operating in the 50 m-200 m range. In some embodiments, the VCSELs may be bottom-emitting large-size VCSEL arrays.

There are several disadvantages for using InP for 1300 nm-1500 nm VCSELs. Multiple quantum well (MQW) InP-based optoelectronics may have good performance, but may have poor lattice matching characteristics when implemented in a DBR. Additionally, the low refractive index contrast may lead to poor DBR mirror performance and poor thermal properties. The solutions for InP-based DBR mirrors still have limitations. For example, devices having GaAlAs/AlAs DBRs on InP still suffer interface losses and low yields. Additionally, the dielectric mirrors used in InP-based DBRs have low thermal performance.

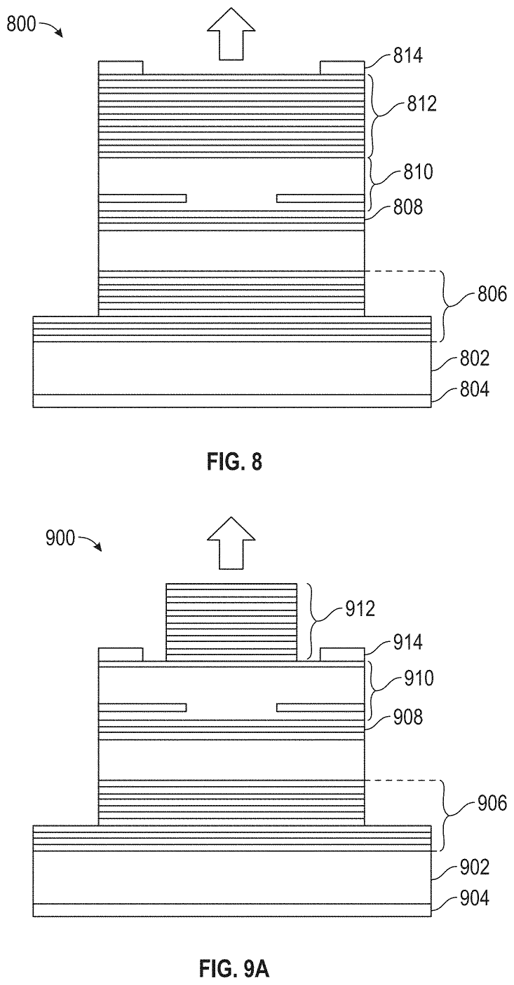

Dilute nitrides offer several performance benefits. Dilute nitrides may form the MQW active region for 1300-1500 nm VCSELs DBRs on GaAs substrates, as shown in FIG. 8. The dilute nitride VCSELs may benefit from use of well-established fabrication and manufacturing practices from high contrast GaAlAs/AlAs DBRs used in 800-900 nm VCSELs or 900 nm range GaAs/AlGaAs platform. The design and implementation of 1300 nm range dilute nitride-on-GaAs may lead to further improvements such as increased wall-plug efficiency (e.g., greater than 20%), increased array size, increased output power, minimization of optical losses, and wavelength extension to 1500 nm. Exemplary dilute nitride materials may include, but are not limited to, GaInNAs and GaInNAsSb.

FIG. 8 illustrates a cross-sectional view of an exemplary stack for a VCSEL, according to some embodiments. The VCSEL 800 may include a substrate 802, a bottom contact layer 804, a first reflector 806, an active region 808, a confinement region 810, a second reflector 812, and a top contact layer 814. The substrate 802 may be overlying the bottom contact layer 804, the first reflector 806 may be overlying the substrate 802, the active region 808 may be overlying the first reflector 806, the confinement region 810 may be overlying the active region 808, the second reflector 812 may be overlying the confinement region 810, and the top contact layer 814 may be overlying the second reflector 812. The substrate 802 may be made from a semiconductor material possessing a corresponding lattice constant. Exemplary materials for the substrate 802 may include, but are not limited to, gallium arsenide (GaAs), indium phosphide (InP), gallium antimonide (GaSb), germanium (Ge), an epitaxially grown material (such as a ternary or quaternary semiconductor), or a buffered or composite substrate. The lattice constant of the substrate 802 may be chosen to minimize defects in materials subsequently grown thereon.

The first reflector 806, the second reflector 812, or both may be a semiconductor DBR, latticed matched to the substrate 802. A DBR may be a periodic structure formed from alternating materials with different refractive indices that can be used to achieve high reflection within a range of frequencies or wavelengths. The thickness of the layers may be chosen to be an integer multiple of the quarter wavelength, based on the target wavelength λ₀. That is, the thickness of a layer may be chosen to be an integer multiple of the target wavelength (e.g., λ₀/(4n), where n is the refractive index of the material at the target wavelength λ₀). A DBR can include, for example, semiconductor materials of Groups III and V of the periodic table. Exemplary materials for the DBR may include, but are not limited to, AlAs, AlGaAs, GaAs, InAs, GaInAs, AlInAs, InGaP, AlInGaP, InGaP, InGaAsP, GaP, InP, AlP, AlInP, and AlInGaAs.

In some embodiments, at least one of the first reflector 806 and the second reflector 812 may be a DBR formed using two different compositions for AlGaAs on a GaAs substrate. The first reflector 806, the second reflector 812, or both may be doped with an n-type dopant or a p-type dopant to facilitate current conduction through the device structure. In some embodiments, the doping type for the first reflector 806 (e.g., n-type or p-type) may be opposite the doping type of the second reflector 812 (e.g., p-type or n-type, respectively).

The active region 808 may include a material capable of emitting a substantial amount of light at a target wavelength of operation. In some embodiments, the active region 808 may include various light emitting structures, such as quantum dots, quantum wells, or the like, which may substantially improve the light emitting efficiency of the VCSEL 800. For example, the active region 808 can include MQWs that emit light in the wavelength range of 1300 nm-1500 nm. In some embodiments, the active region 808 may include more than one material layer.

The VCSEL 800 may also include a confinement region 810. The confinement region 810 can confine the current and/or optical field laterally. In some embodiments, the confinement region 810 may have material properties different from adjacent regions to provide waveguiding and/or to define a region for current injection such that lasing occurs. The confinement region 810 may be formed using one or more methods, such as oxidation, proton implantation, ion implantation, semiconductor etching, semiconductor regrowth, deposition of other materials, or a combination thereof.

The bottom contact layer 804 and the top contact layer 814 may be deposited on the bottom and top, respectively, of the VCSEL 800. In some embodiments, the doping type for the bottom contact layer 804 (e.g., n-type or p-type) may be opposite the doping type of the top contact layer 814 (e.g., p-type or n-type, respectively). The bottom contact layer 804 or the top contact layer 814 may include an opening or metal aperture through which light can be emitted. In the example shown in the figure, the light emission occurs through top surface (e.g., through the top contact layer 814) of the VCSEL. Embodiments of the disclosure may include light emission through the bottom surface via an opening or metal aperture in the bottom contact layer 804.

It will be understood that other layers such as current spreading layers and contacting layers can also be included, more than one confinement region at different depths within the VCSEL may be used, different configurations of electrical contacts (e.g., intracavity contacts) may be used, or the like. For sake of simplicity, the details of other layers in the VCSEL stack are not provided.

Although there are many benefits to implementing the stack of VCSEL 800, such as ease of device fabrication, simple implementation in arrays, simple optical design, uniform pumping of active region, the VCSEL 800 may not be suitable for all applications. For example, the epi doping profiles may be complex, needing to balance resistance and optical losses due to free carrier absorption. The higher reflectivity of VCSEL 800 may result in larger losses, lower slope efficiency, and higher threshold current. The VCSEL 800 may also have a high operating voltage and may be prone to heating at the second reflector 812 when used as a high power device.

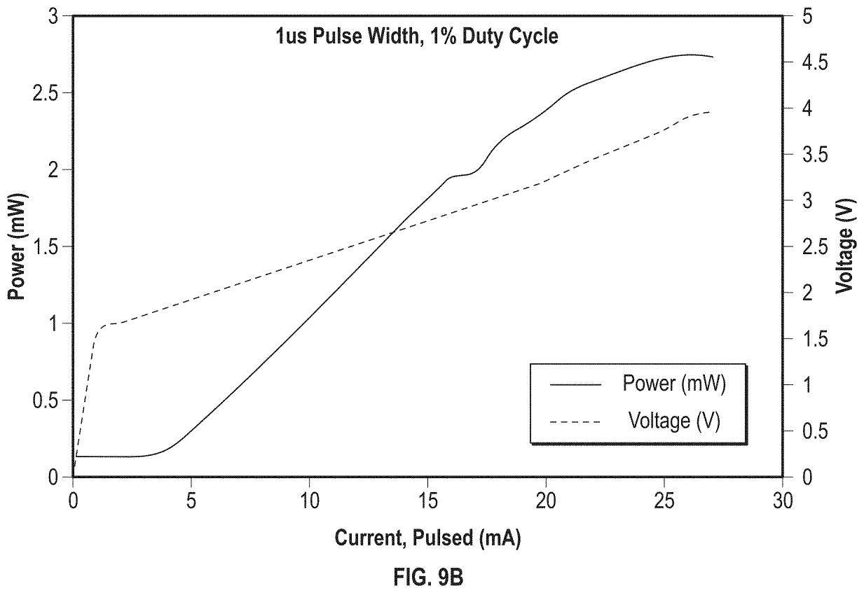

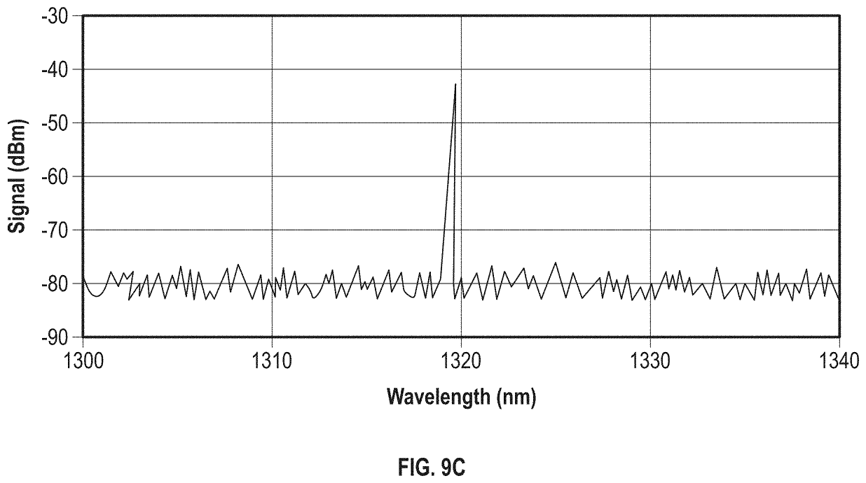

FIG. 9A illustrates a cross-sectional view of an exemplary intracavity VCSEL, according to embodiments of the disclosure. VCSEL 900 may include a substrate 902, a bottom contact layer 904, a first reflector 906, an active region 908, a confinement region 910, a top contact layer 914, and a second reflector 912. The substrate 902, the bottom contact layer 904, the first reflector 906, the active region 908, the confinement region 910, the top contact layer 914, and the second reflector 912 may have one or more structural properties and/or functions similar to the substrate 802, the bottom contact layer 804, the first reflector 806, the active region 808, the confinement region 810, the top contact layer 814, and the second reflector 812 (discussed above). Although not illustrated in the figure, embodiments of the disclosure may include current spreading layers in the stack to limit current crowding.

The substrate 902 may be overlying the bottom contact layer 904, the first reflector 906 may be overlying the substrate 902, the active region 908 may be overlying the first reflector 906, and the confinement region 910 may be overlying the active region 908. In some embodiments, the top contact layer 914 may be overlying the confinement region 910. Additionally or alternatively, the second reflector 912 may be overlying the confinement region 910. The intracavity VCSEL 900 may be an intracavity p-contact VCSEL, but embodiments of the disclosure may include an intracavity n-contact VCSEL.

The configuration of the top contact layer 914 and the second reflector 912 may lead to improved performance for the VCSEL 900. For example, the free carrier optical loss in the second reflector 912 may be reduced (e.g., zero). The slope efficiency may increase (e.g., 72% for VCSEL 900 compared to 60% for VCSEL 800). The threshold current and optical losses may be lower. Additionally, the epi growth of the second reflector 912 may be simpler. VCSEL 900 may be beneficial for applications requiring a higher modulation speed.

FIG. 9B illustrates an output power vs. current density plot of an exemplary intracavity p-contact VCSEL on GaAs substrate, according to embodiments of the disclosure. When operated with a 1 μs pulse width and 1% duty cycle, the threshold current density of the VCSEL is about 5 kA/cm². The VCSEL has a peak emission at 1320 nm, as shown in FIG. 9C, and outputs over 2.7 mW per emitter when operated in pulsed mode.

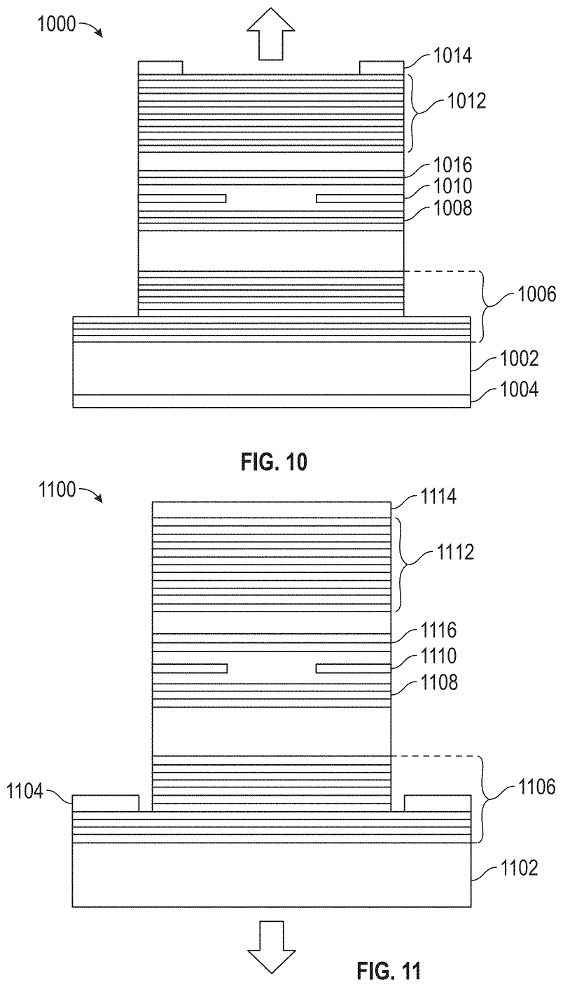

In some embodiments, the disclosed laser structures may include a tunnel junction, such as shown in FIG. 10. VCSEL 1000 may include a substrate 1002, a bottom contact layer 1004, a first reflector 1006, an active region 1008, a confinement region 1010, a second reflector 1012, and a top contact layer 1014. The substrate 1002, the bottom contact layer 1004, the first reflector 1006, the active region 1008, the confinement region 1010, the top contact layer 1014, and the second reflector 1012 may have one or more structural properties and/or functions similar to the substrate 802, the bottom contact layer 804, the first reflector 806, the active region 808, the confinement region 810, the top contact layer 814, and the second reflector 812 (discussed above). Additionally or alternatively, the substrate 1002, the bottom contact layer 1004, the first reflector 1006, the active region 1008, the confinement region 1010, the top contact layer 1014, and the second reflector 1012 may have one or more structural properties and/or functions similar to the substrate 902, the bottom contact layer 904, the first reflector 906, the active region 908, the confinement region 910, the top contact layer 914, and the second reflector 912 (discussed above).

VCSEL 1000 may further include a tunnel junction 1016. The substrate 1002 may be overlying the bottom contact layer 1004, the first reflector 1006 may be overlying the substrate 1002, the active region 1008 may be overlying the first reflector 1006, the confinement region 1010 may be overlying the active region 1008, the second reflector 1012 may be overlying the confinement region 1010, and the top contact layer 1014 may be overlying the second reflector 1012. In some embodiments, the tunnel junction 1016 may be overlying the confinement region 1010, and the second reflector 1012 may be overlying the tunnel junction 1016.

Including the tunnel junction 1016 in the VCSEL stack may lead to reducing optical losses in the second reflector 1012 while making the epi growth of the second reflector 1012 simple and making the fabrication of VCSEL 1000 simple. In some embodiments, VCSEL 1000 may include one or more passivation layers.

Although FIG. 10 illustrates a tunnel junction included in a top emitting VCSEL, embodiments of the disclosure may include a tunnel junction in any of the disclosed laser structures.

Additionally, with dilute nitride materials, bottom-emitting VCSELs arrays may be formed. FIG. 11 illustrates a cross-sectional view of an exemplary bottom-emitting VCSEL, according to embodiments of the disclosure. VCSEL 1100 may include a substrate 1102, a bottom contact layer 1104, a first reflector 1106, an active region 1108, a confinement region 1110, a tunnel junction 1116, a second reflector 1112, and a top contact layer 1114.

The substrate 1102, the bottom contact layer 1104, the first reflector 1106, the active region 1108, the confinement region 1110, the top contact layer 1114, and the second reflector 1112 may have one or more structural properties and/or functions similar to the substrate 802, the bottom contact layer 804, the first reflector 806, the active region 808, the confinement region 810, the top contact layer 814, and the second reflector 812 (discussed above). Additionally or alternatively, the substrate 1102, the bottom contact layer 1104, the first reflector 1106, the active region 1108, the confinement region 1110, the top contact layer 1114, and the second reflector 1112 may have one or more structural properties and/or functions similar to the substrate 902, the bottom contact layer 904, the first reflector 906, the active region 908, the confinement region 910, the top contact layer 914, and the second reflector 912 (discussed above). Additionally or alternatively, the substrate 1102, the bottom contact layer 1104, the first reflector 1106, the active region 1108, the confinement region 1110, the tunnel junction 1116, the top contact layer 1114, and the second reflector 1112 may have one or more structural properties and/or functions similar to the substrate 1002, the bottom contact layer 1004, the first reflector 1006, the active region 1008, the confinement region 1010, the tunnel junction 1016, the top contact layer 1014, and the second reflector 1012 (discussed above).

The first reflector 1106 may be overlying the substrate 1102, the active region 1108 may be overlying the first reflector 1106, the confinement region 1110 may be overlying the active region 1108, the tunnel junction 1116 may be overlying the confinement region 1110, the second reflector 1112 may be overlying the confinement region 1110 (and/or tunnel junction 1116), and the top contact layer 1114 may be overlying the second reflector 1112. In some embodiments, the bottom contact layer 1104 may be overlying the substrate 1102, as shown in FIG. 11.

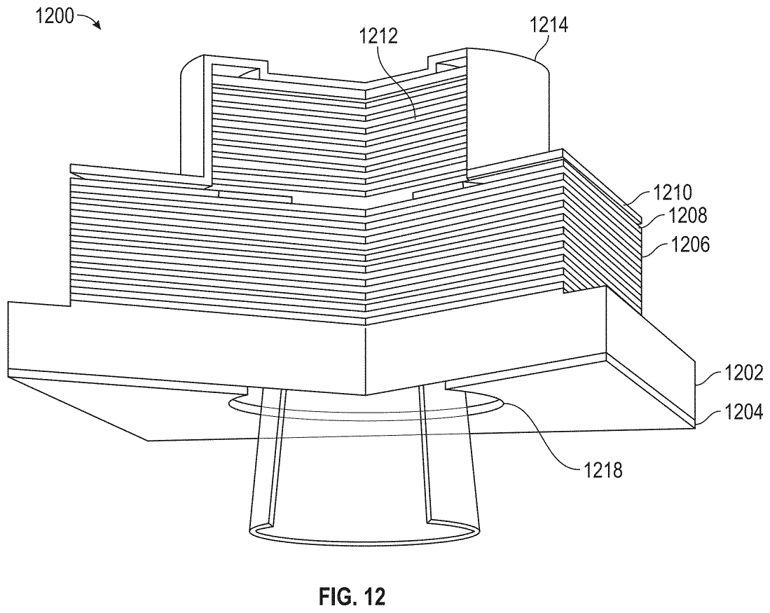

In some embodiments, the substrate may be overlying the bottom contact layer in a bottom-emitting VCSEL, as shown in FIG. 12. VCSEL 1200 may include a substrate 1202, a bottom contact layer 1204, a first reflector 1206, an active region 1208, a confinement region 1210, a second reflector 1212, and a top contact layer 1214. The bottom contact layer 1204 may include an aperture 1218, which may exclude material or may be transparent to allow light emitted by the VCSEL 1200 to be emitted out of the bottom of the VCSEL 1200.

In some embodiments, the substrate 1202 may include GaAs, which may be transparent at 1300 nm and longer wavelengths. A GaAs substrate may allow the VCSEL 1200 to be implemented as a bottom-emitting VCSEL array.

Additionally or alternatively, the top contact layer 1214 (which may be overlying the second reflector 1212) may include a metal. In some embodiments, the top contact layer 1214 may be deposited such that it covers the topmost epilayer of the second reflector 1212. In some embodiments, the top contact layer 1214 may be deposited such that it covers the sides of the second reflector 1212. Covering the topmost epilayer and/or sides of the second reflector 1212 may lead to a larger source-contact, resulting in a more homogeneous carrier distribution and less current crowding. The improved homogeneous carrier distribution and lower current crowding may improve the overall continuous wave operation and dynamic VCSEL properties.

Embodiments of the disclosure may include a laser diode including multiple of the disclosed laser structures (e.g., laser 800, laser 900, the laser 1000, the laser 1100, and the laser 1200). For example, the laser structures may form a monolithically stacked laser (e.g., EEL), such as the monolithically stacked EEL 650 of FIG. 6. One skilled in the art would understand that when including multiple laser structures in the monolithically stacked EEL, only one bottom contact (e.g., bottom contact 604), one top contact (e.g., top contact 614), and one substrate (e.g., substrate 602) may be used.

Additionally or alternatively, the disclosed laser structures may include an oxide aperture in confinement region. In some embodiments, the oxide aperture may have a 10 μm diameter.

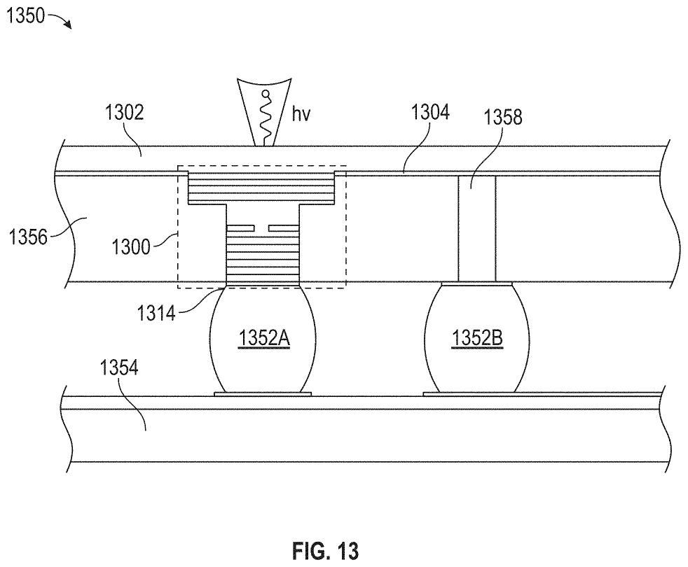

In some embodiments, bottom-emitting VCSELs may be implemented using, e.g., flip-chip packaging. FIG. 13 illustrates a cross-sectional view of an exemplary bottom-emitting VCSEL implemented using flip-chip packaging, according to embodiments of the disclosure. VCSEL 1300 may have one or more structural properties and/or functions similar to VCSEL 1100 and/or VCSEL 1200.

Laser 1350 may include VCSEL 1300, a plurality of contacts 1352, a substrate 1354, an insulator 1356, and a contact 1358. The plurality of contacts 1352 may be electrical contacts formed on the substrate 1354. In some embodiments, the substrate 1354 may include silicon.

In some embodiments, the contacts 1352 may include indium. In some embodiments, the substrate 1354 may include one or more layers to form an electrical plane. VCSEL 1300 may be flipped such that the top contact layer 1314 of VCSEL 1300 may be electrically connected to contact 1352A. The bottom contact layer 1304 may be electrically connected to the electrical contact 1352B via the contact 1358. The contact 1358 may include electroplated gold, for example. In some embodiments, the laser 1350 may include the insulator 1356 for electrically isolating the bottom contact layer 1304 from the top contact layer 1314, for example.

In some embodiments, the substrate 1302 may be thinned down (e.g., using chemical mechanical polishing). A thinned down substrate 1302 may have a thickness (e.g., 200 μm or less). less than an epi wafer. The substrate 1302 may be the substrate that VCSEL 1300 is formed on. The flip-chip packaging may lead to improved thermal performance, which may be critical for large arrays. The improved thermal management may lead to higher output power from the VCSEL.

As shown in the figure, the light from the VCSEL 1300 may be emitted at the top (e.g., opposite from the bottom contact layer 1314). In some embodiments, the flip-chip packaging and bottom-emitting VCSEL may allow the optical plane to be separate from the electrical plane.

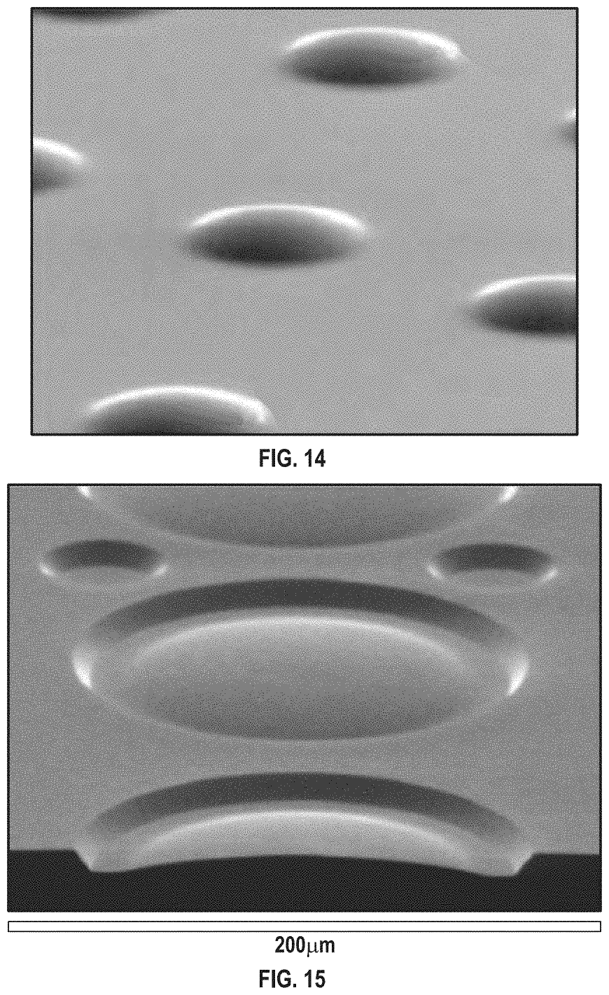

Embodiments of the disclosure may include wafer level integration of optics (i.e., wafer integrated optics) in the substrate (e.g., GaAs substrate). For example, etched microlenses may be formed in the GaAs substrate, as shown in FIG. 14. Another example is shown in FIG. 15, where collimating lenses, beam steering lenses, and/or beam shaping lenses may be formed in the substrate. The beam shaping optics may be formed using hybrid (e.g., wafer bonding) or monolithic integration.

Exemplary Dilute Nitride-on-GaAs Photodetectors (PDs)

Dilute nitride-on-GaAs PDs may achieve good performance along with being lower in costs relative to InGaAs PDs. In some embodiments, dilute nitride-on-GaAs PDs may be 5-20 times lower in costs due to the lower wafer costs, the available wafer sizes, high manufacturing yields, and the mature GaAs wafer processing. As discussed above, dilute nitride-on-GaAs can obtain broadband optical performance (e.g., responsivity) that can span both the visible and infrared wavelengths due to its bandgap tunability. Dilute nitride-on-GaAs may also obtain narrowband optical performance also due its bandgap tunability.

Embodiments of the disclosure can include several types of dilute nitride based PDs such as p-i-n PDs, avalanche PDs (APDs), mid-wave infrared (MWIR) and long-wave infrared (LWIR) (on GaAs substrates or GaSb substrates), and photonics integrated circuits (PICs). The dilute nitride based p-i-n PDs can include narrowband single PDs and arrays for 3D and spectral sensing. The cutoff wavelength of the p-i-n PDs may be around 1450 nm. The dilute nitride based p-i-n PDs can also include broadband arrays for spectral sensing and imaging and/or biomedical applications. The operating wavelength of the p-i-n PDs may be around 450 nm-1450 nm. APDs on GaAs substrates can be for 3D sensing applications and can have a cutoff wavelength around 1450 nm.

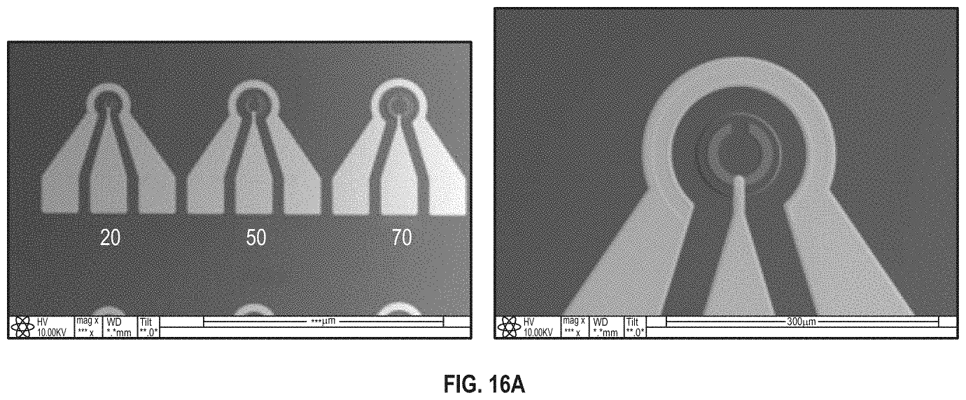

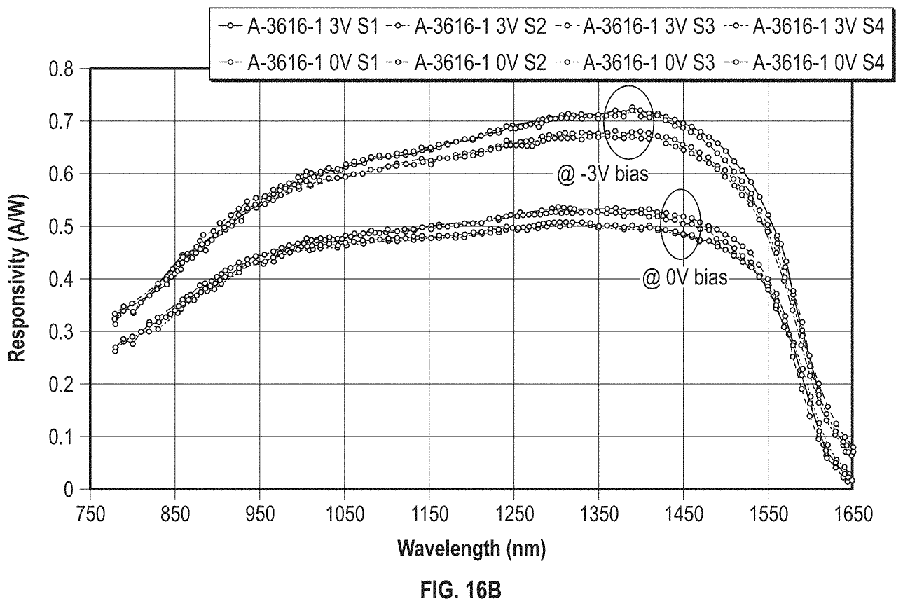

FIGS. 16A-16B illustrate top views and responsivity curves from dilute nitride-on-GaAs based PDs, according to embodiments of the disclosure. As shown in FIG. 16B, longer cutoff wavelengths (e.g., greater than 1.6 μm) may be achieved with dilute nitride-on-GaAs substrates. The cutoff wavelength for dilute nitride-on-GaAs substrates may be extended by optimizing the growth conditions, changing the epi material structure, and/or optimizing wafer processes. For example, the basic bulk material may be improved by minimizing background doping and/or using bandgap and doping engineering to obtain target specifications. Different methods, time durations, temperatures, and/or environment for wafer annealing may improve the material quality. Additionally or alternatively, the epi material structure for the bulk material can be improved. In some embodiments, intraband or inter-subband transitions in quantum-confined heterostructures or structures like Type-II superlattices may be employed.

Embodiments of the disclosure may include enhancing the performance of the dilute nitride-on-GaAs PDs by optimizing the structure and/or fabrication process. For example, the cap layer may be designed with a certain doping, composition, and/or uniformity such that the dark current is reduced. In some embodiments, the dark current may be reduced by grading the doping and/or composition of the materials in the cap layer. Different structures such as a mesa structure, a planar structure (implant or diffused), unipolar nBn, or pBn may be employed. Certain fabrication processes may improve the performance. Exemplary fabrication processes may include passivation of mesa sidewalls to reduce surface dark current and ion implantation to enhance isolation. Additionally or alternatively, the responsivity may be improved by using multi-layer anti-reflecting coatings and/or back-illuminated PDs arrays (including substrate removal for large flip-chip 2D arrays).

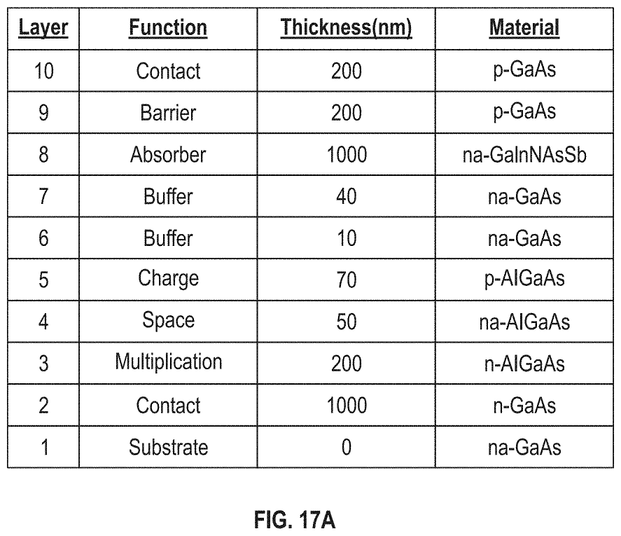

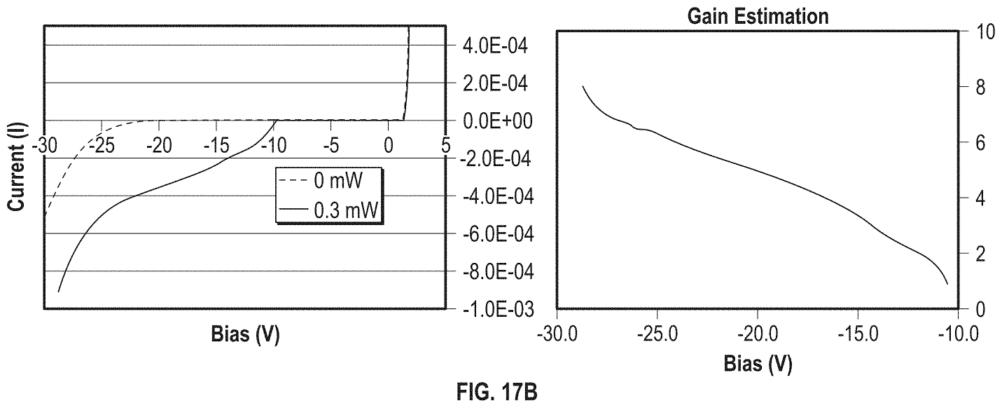

FIG. 17A illustrates an exemplary structure for a dilute nitride-on-GaAs APD, according to embodiments of the disclosure. The APD may have a cutoff wavelength greater than 1600 nm. In some embodiments, the APD may detect light at wavelengths greater than 1300 nm.

The dilute nitride photodetector (e.g., APD) may comprise a substrate, a bottom contact layer, a multiplication layer, a space layer, a charge layer, one or more buffer layers, an absorber layer, and a top contact layer. The bottom contact layer may be overlying the substrate, the multiplication layer may be overlying the bottom contact layer, the space layer may be overlying the multiplication layer, the charge layer may be overlying the space layer, the one or more buffer layers may be overlying the multiplication layer (and/or charge layer), the absorber layer may be overlying the one or more buffer layers, the barrier layer may be overlying the absorber layer, and the top contact layer may be overlying the barrier layer. The absorber layer may include a dilute nitride material. Exemplary dilute nitride materials may include, but are not limited to, GaInNAs and GaInNAsSb.

The APD includes dilute nitride as an absorber and AlGaAs in the multiplication layer. The multiplication layer may be a GaAs/AlGaAs multiplication layer. The GaAs/AlGaAs multiplication layer may be used in combination with variable thickness and composition of the absorbing region in order to achieve spectral and quantum efficiency enhancements. In some embodiments, the AlGaAs in the multiplication layer can include Al_{0.8}Ga_{0.2}As; this material composition may lead to a large ionization coefficient difference for holes and electronics.

Embodiments of the disclosure may include using dilute nitrides in the multiplication layer. Including dilute nitrides in the multiplication layer may increase the hole/electron ionization coefficient in GaAs or InAs. The test results from an exemplary p-i-n diode structure with compositional and thickness variations in the dilute nitride layer are shown in FIG. 17B.

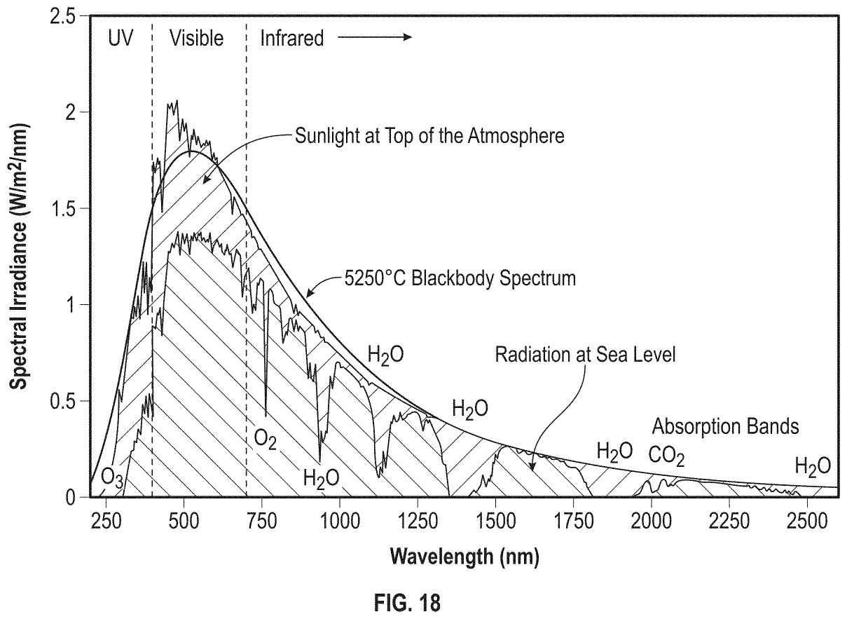

Embodiments of the disclosure can include dilute nitride optoelectronic devices used for sensing in the wavelength range of 1300-1500 nm. As shown in FIG. 18, there is lower solar and atmospheric interference for wavelengths greater than 1300 nm. Additionally, the sun's spectral irradiance has water vapor absorption dips at 905 nm, 940 nm, and 1370-1450 nm.

Embodiments of the disclosure may include flip-chip packaging and using wafer level integration of optics (i.e., wafer integrated optics) in the substrate may be used for the photodetector.

Embodiments of the disclosure may also include the disclosed lasers and photodetectors in a system. In some embodiments, the laser and the photodetector may be formed on the same GaAs substrate. The substrates (e.g., substrates 602, 802, 902, 1002, 1102, 1202, and the one shown in FIG. 17A) used in the laser and/or photodetector may be from GaAs substrates have a diameter of 4″ or greater (e.g., 6″). That is, the laser and/or photodetector may be formed on a 4″ (or 6″) GaAs substrate before being diced and packaged. Embodiments of the disclosure may include flip-chip packaging and using wafer level integration of optics (i.e., wafer integrated optics) in the substrate may be used for the laser, the photodetector, or both in the system.

A laser structure is disclosed. The laser structure may comprise: a bottom contact layer and a top contact layer; a first reflector and a second reflector; an active region including a dilute nitride material; a confinement region; and a substrate comprising GaAs, wherein the laser is configured to generate light at wavelengths greater than 1300 nm. Additionally or alternatively, in some embodiments, the laser structure is further configured to generate light at wavelengths below 1600 nm. Additionally or alternatively, in some embodiments, the substrate is overlying the bottom contact layer; the first reflector is overlying the substrate; the active region is overlying the first reflector; the confinement region is overlying the active region; the second reflector is overlying the confinement region; and the top contact layer is overlying the confinement region. Additionally or alternatively, in some embodiments, the top contact layer includes an opening, and the light is emitted through the opening. Additionally or alternatively, in some embodiments, the substrate is overlying the bottom contact layer; the first reflector is overlying the substrate; the active region is overlying the first reflector; the confinement region is overlying the active region; the second reflector is overlying the confinement region; and the top contact layer is overlying the confinement region. Additionally or alternatively, in some embodiments, the confinement region includes an oxide aperture, the oxide aperture has a 10 μm diameter. Additionally or alternatively, in some embodiments, the laser structure further comprises a tunnel junction, wherein the tunnel junction is overlying the confinement region. Additionally or alternatively, in some embodiments, the substrate is overlying the bottom contact layer; the first reflector is overlying the substrate; the active region is overlying the first reflector; the confinement region is overlying the active region; the second reflector is overlying the confinement region; and the top contact layer is overlying the confinement region. Additionally or alternatively, in some embodiments, the first reflector is overlying the substrate; the bottom contact layer is overlying the substrate; the active region is overlying the first reflector; the confinement region is overlying the active region; the second reflector is overlying the confinement region; and the top contact layer is overlying the second reflector. Additionally or alternatively, in some embodiments, the substrate is overlying the bottom contact layer; the first reflector is overlying the substrate; the active region is overlying the first reflector; the confinement region is overlying the active region; the second reflector is overlying the confinement region; and the top contact layer is overlying the second reflector. Additionally or alternatively, in some embodiments, the bottom contact layer includes an aperture, and the light is emitted through the aperture. Additionally or alternatively, in some embodiments, the laser structure further comprises: a plurality of contacts comprising: a first contact electrically connected to the bottom contact layer, and a second contact electrically connected to the top contact layer; and an insulating layer that electrically isolates the bottom contact layer from the top contact layer. Additionally or alternatively, in some embodiments, the laser structure is a vertical-cavity surface emitting laser (VCSEL). Additionally or alternatively, in some embodiments, the laser structure is included in a monolithically stacked laser, the monolithically stacked laser including at least one tunnel junction.

A photodetector is disclosed. The photodetector may comprise: a bottom contact layer and a top contact layer; a multiplication layer; one or more buffer layers; an absorber layer including a dilute nitride material; and a substrate comprising GaAs, wherein the photodetector is configured to detect light at wavelengths greater than 1300 nm. Additionally or alternatively, in some embodiments, the bottom contact layer is overlying the substrate; the multiplication layer is overlying the bottom contact layer; the one or more buffer layers is overlying the multiplication layer; the absorber layer is overlying the one or more buffer layers; the barrier layer is overlying the absorber layer; and the top contact layer is overlying the barrier layer. Additionally or alternatively, in some embodiments, the multiplication layer includes AlGaAs.

A system is disclosed. The system may comprise: a laser including: a first reflector and a second reflector, an active region including a dilute nitride material, a confinement region, and a first substrate comprising GaAs, wherein the laser is configured to generate light at wavelengths greater than 1300 nm; and a photodetector comprising: a multiplication layer, one or more buffer layers, an absorber layer including a dilute nitride material, and a second substrate comprising GaAs, wherein the photodetector is configured to detect light at wavelengths greater than 1300 nm. Additionally or alternatively, in some embodiments, one or more of: the first substrate and the second substrate include wafer integrated optics. Additionally or alternatively, in some embodiments, one or more of: the first substrate and the second substrate are from a GaAs substrate having a 6″ diameter.

Although examples of this disclosure have been fully described with reference to the accompanying drawings, it is to be noted that various changes and modifications will become apparent to those skilled in the art. Such changes and modifications are to be understood as being included within the scope of examples of this disclosure as defined by the appended claims.

1. A laser structure comprising:
a bottom contact layer and a top contact layer;
a first reflector and a second reflector;
an active region including a dilute nitride material;
a confinement region; and
a substrate comprising GaAs,
wherein the laser is configured to generate light at wavelengths greater than 1300 nm.

2. The laser structure of claim 1, wherein the laser structure is further configured to generate light at wavelengths below 1600 nm.

3. The laser structure of claim 1, wherein:
the substrate is overlying the bottom contact layer;
the first reflector is overlying the substrate;
the active region is overlying the first reflector;
the confinement region is overlying the active region;
the second reflector is overlying the confinement region; and
the top contact layer is overlying the confinement region.

4. The laser structure of claim 1, wherein the top contact layer includes an opening, and the light is emitted through the opening.

5. The laser structure of claim 1, wherein:
the substrate is overlying the bottom contact layer;
the first reflector is overlying the substrate;
the active region is overlying the first reflector;
the confinement region is overlying the active region;
the second reflector is overlying the confinement region; and
the top contact layer is overlying the confinement region.

6. The laser structure of claim 1, wherein the confinement region includes an oxide aperture, the oxide aperture has a 10 μm diameter.

7. The laser structure of claim 1, further comprising a tunnel junction, wherein the tunnel junction is overlying the confinement region.

8. The laser structure of claim 1, wherein:
the substrate is overlying the bottom contact layer;
the first reflector is overlying the substrate;
the active region is overlying the first reflector;
the confinement region is overlying the active region;
the second reflector is overlying the confinement region; and
the top contact layer is overlying the confinement region.

9. The laser structure of claim 1, wherein:
the first reflector is overlying the substrate;
the bottom contact layer is overlying the substrate;
the active region is overlying the first reflector;
the confinement region is overlying the active region;
the second reflector is overlying the confinement region; and
the top contact layer is overlying the second reflector.

10. The laser structure of claim 1, wherein:
the substrate is overlying the bottom contact layer;
the first reflector is overlying the substrate;
the active region is overlying the first reflector;
the confinement region is overlying the active region;
the second reflector is overlying the confinement region; and
the top contact layer is overlying the second reflector.

11. The laser structure of claim 1, wherein the bottom contact layer includes an aperture, and the light is emitted through the aperture.

12. The laser structure of claim 1, further comprising:
a plurality of contacts comprising:
a first contact electrically connected to the bottom contact layer, and
a second contact electrically connected to the top contact layer; and
an insulating layer that electrically isolates the bottom contact layer from the top contact layer.

13. The laser structure of claim 1, wherein the laser structure is a vertical-cavity surface emitting laser (VCSEL).

14. The laser structure of claim 1, wherein the laser structure is included in a monolithically stacked laser, the monolithically stacked laser including at least one tunnel junction.

15. A photodetector comprising:
a bottom contact layer and a top contact layer;
a multiplication layer;
one or more buffer layers;
an absorber layer including a dilute nitride material; and
a substrate comprising GaAs,
wherein the photodetector is configured to detect light at wavelengths greater than 1300 nm.

16. The photodetector of claim 15, wherein:
the bottom contact layer is overlying the substrate;
the multiplication layer is overlying the bottom contact layer;
the one or more buffer layers is overlying the multiplication layer;
the absorber layer is overlying the one or more buffer layers;
the barrier layer is overlying the absorber layer; and
the top contact layer is overlying the barrier layer.

17. The photodetector of claim 15, wherein the multiplication layer includes AlGaAs.

18. A system comprising:
a laser including:
a first reflector and a second reflector,
an active region including a dilute nitride material,
a confinement region, and
a first substrate comprising GaAs,
wherein the laser is configured to generate light at wavelengths greater than 1300 nm; and
a photodetector comprising:
a multiplication layer,
one or more buffer layers,
an absorber layer including a dilute nitride material, and
a second substrate comprising GaAs,
wherein the photodetector is configured to detect light at wavelengths greater than 1300 nm.

19. The system of claim 18, wherein one or more of: the first substrate and the second substrate include wafer integrated optics.

20. The system of claim 18, wherein one or more of: the first substrate and the second substrate are from a GaAs substrate having a 6″ diameter.
